(19) United States
(12) Patent Application Publication
(10) Pub. No.: US 2013/0152989 A1
(43) Pub. Date: Jun. 20, 2013

(54) THERMOELECTRIC GENERATOR HAVING AN INTEGRATED PRETENSIONED MOUNTING

(71) Applicants: Ilona Krinn, Moehringen (DE); Martin Koehne, Asperg (DE); Franz Wetzl, Mundelsheim (DE); Frank Felten, Karlsruhe (DE); Manfred Schmitt, Heppenheim (DE); Winfried Ziegler, Maulbronn (DE); Miroslaw Brzoza, Vaihingen/Enz (DE); Patrick Glaser, Stuttgart (DE)

(72) Inventors: Ilona Krinn, Moehringen (DE); Martin Koehne, Asperg (DE); Franz Wetzl, Mundelsheim (DE); Frank Felten, Karlsruhe (DE); Manfred Schmitt, Heppenheim (DE); Winfried Ziegler, Maulbronn (DE); Miroslaw Brzoza, Vaihingen/Enz (DE); Patrick Glaser, Stuttgart (DE)

(21) Appl. No.: 13/577,066

(22) PCT Filed: Dec. 20, 2010
(86) PCT No.: PCT/EP10/70183

§ 371 Date: Dec. 5, 2012

(30) Foreign Application Priority Data
Feb. 3, 2010 (DE) 10 2010 001 536.9

(51) Int. Cl. F01N 5/02; H01L 35/34; H01L 35/30

(52) U.S. Cl. CPC F01N 5/02; H01L 35/30; H01L 35/34
USPC 136/210; 136/201

(57) ABSTRACT

A thermoelectric generator and a method for manufacturing a thermoelectric generator are described. The thermoelectric generator, having a housing in which at least one heat source tube, at least one heat sink tube, and at least one generator element are between the heat source tube and the heat sink tube. A pretension mounting device is in the housing and provides an elastic force via which the tubes are pretensioned relative to one another and which compresses the tubes and the generator element in-between. An inner side of the housing of the pretension mounting device forms a support for the pretension mounting device, which is acted upon by a counterforce to the elastic force of the pretension mounting device.

### BACKGROUND INFORMATION

Thermoelectric generators may be used to utilize the thermal energy of internal combustion engines, for example. For example, German Patent Application No. DE 10 2006 057 662 A1 relates to a vehicle having a thermoelectric generator in which heat sources and heat sinks are stacked perpendicularly to one another in their longitudinal extension, thermoelectric elements being present between the individual heat sources and heat sinks. The heat source and the heat sink are provided by a plurality of heat-conducting tubes, the thermoelectric generator elements being integrated between the tubes.

In particular during the use of internal combustion engines, strong temperature fluctuations occur which impair the mechanical connections between the generator elements and medium-conducting tubes. Even slight gaps greatly reduce the efficiency of the generator elements, since their efficiency is highly dependent on the temperature difference, and even small air gaps result in significant thermal resistance.

Therefore, the approach is used for a radial elastic force to externally act upon tubes and heating elements in order to press the generators onto the tubes. The radially outwardly extending spring elements, which are arranged around the tubes and generator elements in a convoluted manner, are fundamentally unsuitable for insertion, also on the inside, between the tubes and generator elements, since conventional spring elements and systems necessarily generate a high thermal resistance. Conventional thermoelectric generators having radially acting spring elements, therefore have a design in which initially the heat sink, the heat source, and the generator elements are integrated with one another, and spring elements act upon the integrated structure solely from the outside, supported by an outer circumferential mounting.

This type of structure is described in U.S. Published Patent Application No. 2005/0172993 A1, in which an exhaust pipe forms the center around which thermoelectric elements are arranged, and on which heat sinks in turn are directly situated. Spring elements are provided only by an outer circumferential band which bears elastic washers on the interior, to which an outer surface of the heat sinks is connected. This type of elasticity limits the heat exchanger structure to a concentric design in which only an outer layer may be acted upon by elastic force. Transmitting an external elastic force into the interior of the generator does not provide the desired mechanical stability for internal components.

Thus, with respect to their degree of integration, conventional thermoelectric generators are limited to single-layer concentric structures. The conventional spring structure is not suitable for high temperature differences or temperature changes, since when there are great temperature differences, many of the generator elements, in particular the inner generator elements, lose their thermal coupling via heat-related gaps without the ability to compensate for this via spring action, since commonly provided spring elements provide a high thermal resistance.

### SUMMARY

An example thermoelectric generator according to the present invention allows any desired degree of integration without the interior generator elements being acted upon by an insufficient elastic force. The system according to the present invention in particular allows pretensioning of the generator elements and associated tubes (which are used as a collecting source or heat sink) which is independent of the position of the particular generator element in the thermoelectric generator. As noted above, conventional spring element systems allow only the exterior elements to be acted upon by an elastic force, whereby generator elements situated farther inside do not experience a sufficient elastic force to maintain contact with the heat sink and with the heat source in the event of temperature changes or also vibrations. However, the structure according to the present invention allows any given number of tubes and generator elements to be combined into a compact generator, so that the specific surface, the integration density, or the generator power relative to the generator volume may automatically be greatly increased. At the same time, the device according to the present invention may be provided with simple means, in particular without spring elements and support structures which are concentrated around the actual generator, which form the counterbearing for the overall elastic force. The example system according to the present invention allows space-saving integration of the elements, which press on the particular tubes over a wide temperature range. In particular, the circumference of the generator, while maintaining the same power (or higher power), is reduced compared to the related art.

In accordance with the present invention, the spring elements are integrated into the generator structure, and are not provided around the outer tubes. While conventional systems merely provide for exertion of external force and for only the outer tubes to be acted upon by elastic force, the example embodiment of the present invention provides that a pretension mounting device is provided which pretensions the tubes themselves relative to one another, thus compressing the generator element situated in-between with the aid of the tubes. The element which generates the elastic force is provided, at least partially, between the tubes, in the tubes, by the tubes themselves, or, for example as a subcomponent, at the end face of the tubes. The pretension mounting element exerts the force directly on the tubes, either by providing spring elements in the tubes themselves or at the end faces of the tubes (as a subcomponent), or by suitable mounting of the tubes, in order to have their elastic force or the elastic force of an end-face mounting act directly on the tubes if needed. The tube walls themselves are used as spring elements according to the present invention, optionally alternatively or in combination with an end-face mounting which provides a base plate, or by spring elements situated inside the tubes, and thus provide no bridging thermal resistance between a generator element and a tube exterior. In addition to the elastic force which is provided between the outer housing and the exterior generator elements, the system according to the present invention, in particular the pretension mounting device, allows that in a similar manner, not just tubes situated in the outermost layer are acted upon by an elastic force. According to the present invention, the pretension mounting device is provided not just on the outside of the thermoelectric generator, but also inside the generator (i.e., inside the tubes or at the end faces), together with force distribution elements or spring elements which are provided by the tube walls themselves, in order to distribute the elastic force directly over internal, i.e., all, components. Similarly, the device according to the present invention generates a predetermined elastic force which is less than a defined maximum elastic force, generally independently of the operating temperature interval.

The thermoelectric generator according to the present invention includes a housing in which at least one heat source tube, at least one heat sink tube, and at least one generator element are situated, the generator element being situated between the various tubes (i.e., between a heat source tube and a heat sink tube). The pretension mounting device according to the present invention provides an elastic force which acts between the tubes, i.e., which is used for pretensioning the tubes relative to one another. The elastic force acts directly on the tubes themselves and is not transmitted from the outside toward the inside from tube to tube; this type of transmission would allow the magnitude of the elastic force from the outside toward the inside to drop considerably. According to the present invention, the pretension mounting device acts directly on the tubes themselves, regardless of their distance from the center of the thermoelectric generator. The pretension mounting device thus presses generator elements together by exerting pressure on tubes which directly adjoin the generator element. The pretension mounting device is also distributed over the cross section of the generator, and exerts force directly on the tubes in that the pretension mounting device is either situated directly at the end faces of the tubes, or is provided by the tube walls themselves, or is generated by spring elements present in the tubes. Direct mechanical contact thus results between the pretension mounting device and the tubes, in particular as the result of the pretension mounting device and tubes (sometimes) being identical, due to a force fit between the pretension mounting device and the tubes, or due to a form fit between the pretension mounting device and the tube. This applies to all tubes of the thermoelectric generator, in particular the interior tubes.

For the pretension mounting device, an inner side of the housing is used as a counterbearing. The interior of the housing thus provides a support for the pretension mounting device, the support being acted upon by a counterforce of the elastic force of the pretension mounting device due to the balancing of the elastic forces. The magnitude of the counterforce may correspond to the elastic force exerted by the pretension mounting device on the tubes. However, in particular the overall magnitude of the elastic force of the pretension mounting device which is exerted on the tubes is greater than the magnitude of the counterforce, since the tubes are also acted upon by tension among one another; this does not necessarily have to result in an equal counterforce which acts on the housing, since the forces act between the tubes themselves and are therefore distributed by pretentional the mounting device. The pretension mounting device is used on the one hand for mounting the tubes, and on the other hand for generating pretension. The mounting allows displacement of the tubes relative to one another in order to compensate for movements under strong temperature changes caused by differing thermal expansions. The mounting provided by the pretension mounting device may also be provided by an elastic, i.e., pretensioned, mounting, it being possible to compensate for the elastic forces acting upon the tubes due to movement or also deformation of the tubes.

A first specific embodiment provides that the pretension mounting device is implemented by clamping the tubes between base plates. The surface of the base plates has micro- or macrostructures in order to hold the end faces of the tubes in place. The force with which the base plates press on the end faces of the tubes results in a force fit having a defined maximum adhesive force which results from the material and in particular from the microstructures, together with the contact force (i.e., perpendicular force) with which the tubes act on the base plates. A metal surface which has been roughened, for example by brushing or the like, is particularly suited as a microstructure.

Profiles, elevations, or depressions which are introduced into the surface, for example by embossing or in some other way, are suited as macrostructures. Particular specific embodiments for the surfaces are described in greater detail below. The pretension mounting device is formed by the base plates, in particular by the surfaces of the base plates, and by the end faces of the tubes. The base plates themselves may be provided with an elastic design. Alternatively or in combination, the tubes themselves may be provided with an elastic design so that the tube walls themselves provide the spring action. In particular, the tubes are used to transmit the spring action over the length of the tubes, so that the tubes are designed with a slight elasticity.

According to one preferred specific embodiment, the tubes are generally rigid, and exert a strong elastic force even for slight deflections. To avoid the situation that the elastic force with which the generator elements or the tubes are clamped is uncontrollable and in particular remains below a maximum value for which the structures, in particular the generator elements, may be damaged, the nonintegral bond between the tube and the surface provides a bearing which at low forces initially holds the tubes in place, but which at higher forces which exceed the maximum radial force or maximum adhesive force provides for displacement of the tubes to thus reduce the deflection. This is made possible in that the base plate or the tubes (or both) is/are provided with an at least slightly elastic design, i.e., is/are made of elastic material and has/have an elastic structure. Based on the elasticity and the dimensions of the base plate and tube, the maximum adhesive force and the maximum radial force above which the force-fit or form-fit connection between the tube and the base plate gives way and allows slippage may be precisely provided as a function of the pretensioning of the tubes in the longitudinal direction.

The distinction between a form fit and a force fit depends generally on the consideration of the structures of the base plate surfaces. In addition, microstructures which rub against one another may be regarded as a detachable form fit if elevations of the microstructures which give way due to their elasticity or plasticity are considered as a form-fitted shape. The magnitude of the maximum adhesive force and of the maximum radial force thus also depends on the magnitude of the micro- or macrostructure, the materials used, and the flexural strength of the base plates and of the tubes. Since all necessary parameters may be easily ascertained, for example by using a materials table containing elasticity and adhesive force data, those skilled in the art are familiar with how the individual components must be designed if a certain maximum adhesive force or maximum radial force is to be generated. Similarly, the pretensioning of the tubes in the longitudinal direction is a function of the material constants and the dimensions of the components, in particular the thickness of the base plates, the wall thickness of the tubes, and the length and materials of the tubes.

The surfaces or base plates themselves may be roughened using any desired method, and thus have microstructures via which the adhesive force is defined. In addition, layers may be applied to the base plates in a targeted manner to increase or decrease the adhesion. However, one preferred specific embodiment provides that the surface of the base plates or the base plates themselves is/are provided with macrostructures which, for example, are larger than 100 μm, larger than 200 μm, or larger than 500 μm, in particular larger than 1 mm or 2 mm. When base plates having a wave-shaped profile are used, their surfaces also have repeating elevations and depressions. The macrostructures may have a grid pattern composed of straight channels, for example channels which extend linearly along the surface in two different directions. The macrostructures may also be provided with flat grooves having a depth of 0.5 mm or 1 mm, for example. The elevations and depressions may be one-dimensional and extend only away from the surface, or may extend away from the surface and also along the surface in one direction. In particular, the macrostructures are designed in such a way that they are not able to tilt with the end faces of the tubes. For this purpose, the cross section of the elevations or depressions is provided with areas which extend at an angle of much less than 90° relative to the surface, for example at a maximum angle of 60°, 45°, or 30°. Tilting is thus prevented, even if the macrostructures are particularly large. Structures are preferably used which have surfaces that do not tilt in multiple displacement directions. For fairly small macrostructures, as a result of their elasticity it may already be provided that they are not able to tilt with the tubes, so that they do not necessarily have to have this type of cross section. In addition, a continuous progression of the structures is preferred, for example, a wave-shaped progression or a triangular progression (not a sawtooth progression).

The base plate itself is integrally joined to the housing, or fastened to the housing in some other manner, in such a way that the base plates in the housing are not able to move in the direction of the longitudinal extension.

Further specific embodiments provide that only one type of tube is connected to the base plates via a force fit or a form fit, while the other type of tube may be integrally joined to the base plate, for example by welding. Thus, in particular the heat sources may be integrally joined to the base plate, for example by a welded connection, and only the cooling channels are displaceably situated on the base plate. In addition, one base plate may be welded to one type of tube, and the other base plate may be welded to the other type of tube, one type of tube always being situated on each of the base plates via a form fit or a force fit, and the other type of tube being connected to the base plate by integral joining. All heat source tubes are denoted as one type of tube, and all heat sink tubes are denoted as the other type of tube. If the heat sink tubes are welded to the base plates, and the heat source tubes are situated on the base plates by integral joining or form fit, this does not result in structural problems, even if the operating temperatures change strongly, since the heat source tubes are always exposed to a higher temperature than the heat sink tubes, and therefore automatically undergo greater thermal expansion.

The described specific embodiments may also be provided with a shared collecting tube which is situated at the ends of the respective tubes and which connects the tubes to one another. The collecting tube extends perpendicularly to the longitudinal extension of the heat sink tubes or heat source tubes, and preferably has an elastic or flexible design. For the flexible design, the collecting tube does not generate pretensioning for the tubes extending perpendicularly thereto, so that the pretension mounting device generally generates all of the tensioning forces. Alternatively, however, the collecting tube may be provided with an elastic design in order to provide at least a portion of the pretension mounting device. These types of specific embodiments are described in greater detail below.

According to a further aspect of the present invention, the pretension mounting device includes spring elements which are not provided by the tube wall or by the heat source tube or heat sink tube itself, optionally together with the base plates; instead, the pretension mounting device is provided by individual spring elements. These spring elements are situated inside the heat sink tube or inside the heat source tube, under pretensioning in this tube. The heat sink tube or heat source tube has a wall which is elastic and which is able to transmit the deformation, resulting from the pretensioning of the spring elements in the tubes, into the area (external area) surrounding the tube. The pretensioning of the spring elements acts on oppositely situated sections of the inner sides of the tube. The direction of action is radial, relative to the longitudinal axis of the heat source tube or of the heat sink tube in which the spring elements are situated. Since the tube in which the spring elements are provided has an elastic design (due to an elastic configuration of the tube wall), the pretensioning is relayed to an adjacent tube, in particular via the generator elements. In other words, as a result of the flexible or elastic design of the tubes, the deformation caused by the interior spring elements is used for clamping the generator elements. The spring elements themselves have a cross-sectional area which is much smaller than the cross-sectional area of the channel which is defined by the tubes in which the spring element is provided. The spring element, and in particular its cross section, is therefore designed to allow a flow inside the tube and to only slightly influence the flow.

In one alternative specific embodiment, individual spring elements are likewise used, except that multiple heat sink tubes are situated between end sections (i.e., at end faces). The end sections protrude beyond the heat source tubes. In addition, the spring elements may be situated between end sections of the heat source tubes, these spring elements extending beyond the heat sink tubes in the longitudinal direction of the tubes. In general, some of the heat sink tubes or heat source tubes may protrude in length beyond the other tubes, the spring elements being provided between the protruding tubes and being acted upon by pretensioning, in particular pretensioning which pushes apart the tubes which are connected via the spring elements. Thus, the spring elements themselves exert force directly on the end sections themselves which protrude with respect to other tubes in the longitudinal direction. The spring elements which engage at the end sections of the tubes may take over the position of the base plates. Due to the rigidity of the heat sink tubes and heat source tubes, the force exerted by the spring elements is distributed along the longitudinal extension of the tubes. In particular, oppositely situated end sections of the tubes which are situated at the same end of the generator are pretensioned relative to one another by the spring elements.

In one design in which the spring elements are situated inside the heat sink tube and inside the heat source tube, the tubes have an elastic or also flexible design, in that the wall thickness or the material of the tubes is selected in such a way that deformation by the spring elements is possible in order to compensate for height tolerances. Since this depends on the elastic force of the spring elements, the wall thickness or also the material of the tubes is determined by the spring elements. The wall thickness may be extremely thin, for example in the form of a steel foil or the like, depending on the medium which is conducted in the tube. The spring elements are provided with a flow-permeable structure, in particular as the result of the design of the profile. The spring elements are provided with the aid of leaf springs or wire springs, for example, which are optionally aligned along the longitudinal extension of the tube, and as a result of the alignment a minimum profile area is provided inside the tube cross section. In particular, the spring elements may be provided by metal foam which is pretensioned in the tube. For this purpose, either the metal foam may be introduced into the tube intensely cooled, or the tube may be initially heated before the metal foam (optionally cooled) is introduced. Balancing the temperatures results in pretensionings of the metal foam which are directed toward the wall of the tube. The metal foam has an open-pore design and allows fluid to pass through. In particular when liquid, for example cooling water, is used as fluid, the metal foam allows a much larger specific surface, so that the heat transfer to the liquid medium is greatly increased. The metal foam is integrally joined to the wall, resulting in good heat conduction. Installation is carried out by precompression.

In designs in which the spring elements are provided between end sections of the tubes (i.e., between end sections of tubes which protrude with respect to other tubes), the spring elements are provided by sections of a tube which is elastic in its longitudinal direction. This type of collecting tube, via its sections, connects the end sections of the tubes. The heat source tubes or heat sink tubes which protrude beyond the heat sink tubes or heat source tubes, which have no end section that is connected to the collecting tube, are thus connected to one another in mutual fluid communication. The elastic collecting tube, in particular the elasticity thereof in its longitudinal direction, provides the pretensioning between the end sections. The collecting tube extends generally perpendicularly with respect to the tubes, i.e., with respect to the heat sink tubes and heat source tubes and their end sections.

In one alternative specific embodiment, a similar collecting tube is provided which, however, is flexible and which exerts no force on the tubes, in particular not on the end sections. Except for the deformation behavior, the flexible collecting tubes may be provided in the same way as the elastic collecting tubes. However, when flexible collecting tubes are used, a pretension mounting device according to the present invention is provided which provides all of the pretensioning between the tubes. For the above-described use of elastic collecting tubes, the collecting tube itself provides the pretension mounting device. An elastic collecting tube is used on the one hand for movably mounting the heat source tubes or heat sink tubes, and on the other hand for exerting pretensioning between the tubes. The flexible collecting tube as well as the elastic collecting tube are connected to the tubes which form the protruding end sections.

The example thermoelectric generator according to the present invention may also include a flow control system which is situated at the end faces of the tubes, i.e., the heat sink tubes and the heat source tubes. The flow control system is tapered toward the tubes, and opens in a direction facing away from the tubes, for example in the direction of a collecting chamber. This type of collecting chamber is situated on at least one of the end faces of the heat sink tubes and the heat source tubes, and is in fluid contact with all similar tubes, i.e., with all heat source tubes or with all heat sink tubes.

The collecting chamber may also be in fluid contact with only a portion of similar tubes. The flow control system is provided between the collecting chamber and the end faces of the tubes, i.e., the inlets of the tubes. The flow control system has a taper for each tube, preferably a curved, continuous taper, or a taper whose tapering angle changes abruptly. However, curved elements may also be connected to sections whose tapering angle changes abruptly.

In particular for specific embodiments which include base plates, the base plates have openings at the inlets of the tubes, i.e., at the end faces of the tubes, to allow a fluid flow. The openings in a base plate are associated with only one type of tube, i.e., the heat sink tube or the heat source tube, the base plate providing no opening or connection for the respective other type of tube. When two base plates are used, the base plates are associated with different types of tubes. A collecting chamber via which the tubes are acted upon by the suitable medium is connected to the base plates on the side facing away from the tubes.

When collecting tubes are used, on one side of the tubes the collecting tubes connect only a certain type of tube, namely, the type of tube whose end sections protrude beyond the other tubes. The tubes of the other type, i.e., the recessed tubes, is in fluid communication with a collecting chamber which is joined to the tubes on the same side as the collecting tube. The recessed tubes are supplied, via the collecting chamber, with a medium which is different from the medium that is present in the collecting tube. Since the medium in the collecting tube in principle has a different temperature than the medium in the collecting chamber, thermal insulation is preferably provided which separates the collecting tube from the collecting chamber in terms of heat transfer. Otherwise, the collecting tube may partially extend through the collecting chamber; however, the collecting tube and the collecting chamber are fluid-mechanically separated, and also preferably heat-insulated with respect to one another.

The present invention may also be implemented by an example method for manufacturing the example thermoelectric generator according to the present invention. At least one heat source tube, at least one heat sink tube, and at least one generator element are introduced into a housing, the generator element being situated between the heat source tube and the heat sink tube. In addition, a pretension mounting device is situated in the housing which generates an elastic force for exerting the pretensioning via which the tubes are pretensioned relative to one another, and the tubes thus compress the generator element situated in-between. Either the tubes are clamped in the pretension mounting device, for example if the pretension mounting device includes base plates, or the pretension mounting device is introduced into the tubes, i.e., clamped in the tubes under pretensioning. This is the case, for example, when the pretension mounting device is provided by individual spring elements present in the tubes, for example by inserting leaf spring elements, wire spring elements, or metal foam under pretensioning. In addition to the pretensioning between the tubes, according to the method pretensioning is also provided between the tubes and the inner sides of the housing, in that the interior of the housing is acted upon by a force, as a result of which the pretension mounting device is supported by the housing.

The tubes, i.e., the heat source tubes, the heat sink tubes, and the collecting tubes, as well as the housing and the base plates are made of metal, preferably steel, aluminum, or copper. When leaf springs or wire springs are used, these are preferably made of spring steel, in particular having a weather-resistant coating to protect the spring elements from the corresponding heating medium. When metal foam is used, it is preferably made of aluminum or other metals or alloys. When metal foam is used as pretensioned spring elements, the pretensioning force is set by suitably selecting the pore size, as well as the intensity of the deformation which results in the pretensioning.

The housing itself may also have flanges which are situated on both sides of the generator. The collecting chamber is situated inside the housing, between the flange and the end faces of the tubes. In addition, connections may be provided which are connected via flexible connecting tubes to the particular heat sink tube or heat source tube. In particular, the flange is used for supplying gaseous media, in particular hot combustion gas. This results in low back-pressure for an internal combustion engine to be connected thereto. The generator also includes, preferably on both sides, a flexible or also elastic collecting tube which in each case connects the heat sink tubes to one another on both sides of the generator in order to supply and discharge cooling fluid to and from the generator.

Seebeck or Peltier elements are particularly suited as a generator element. The generator elements preferably include doped semiconductor material, in particular at least one body which is n-doped, and at least one additional body which is p-doped. The generator elements also include an electrically conductive connecting contact which connects the differently doped semiconductor elements to one another, and a terminal contact for the positive pole or negative pole.

### BRIEF DESCRIPTION OF THE DRAWINGS

FIG. 1 shows a first specific embodiment of a thermal generator according to the present invention in the longitudinal section.

FIG. 2 shows a partial aspect of a second specific embodiment of a thermal generator.

FIG. 3 shows a schematic diagram of a third specific embodiment of a thermoelectric generator.

FIG. 4 shows a fourth specific embodiment of a thermoelectric generator according to the present invention in the longitudinal section.

### DETAILED DESCRIPTION OF EXAMPLE EMBODIMENTS

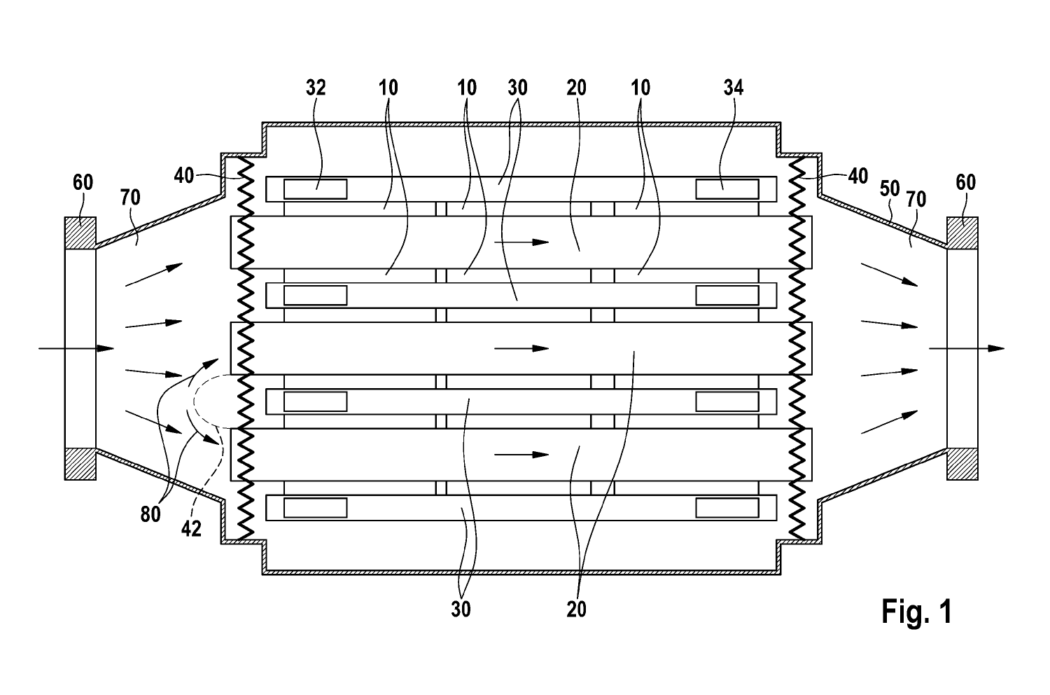

The first specific embodiment of a thermoelectric generator illustrated in FIG. 1 includes generator elements 10 which are situated around a heat source tube 20 composed of multiple heat source tubes 20. A heat sink tube 30 in the form of a cooling channel for cooling fluids is situated at the sides of the generator elements 10 facing away from heat source tube 20. Each generator element is thus connected on both sides between a heat source tube in the form of an exhaust gas channel 20 and a heat sink tube in the form of a cooling channel 30. Tubes 20, 30 and generator elements 10 are situated in a housing 50 which is closed along its periphery and which has two open ends in order to introduce and discharge heat source medium into and from the generator. The openings are in the form of a flange 60. The heat sink tubes have a connection 32, 34, respectively, at each end, the connections 32 of all heat sink tubes on one side of the generator being connected to one another, and all connections 34 of the oppositely situated ends of the heat sink tubes being connected to one another. The collecting lines at both ends have an outwardly leading connection in each case, not illustrated in FIG. 1 for the sake of clarity. These connections in each case are guided through the housing to the outside.

The heat sink tubes are held at both sides by a base plate 40 in each case, base plate 40 holding heat sink tubes 30 in a press fit. As symbolically illustrated, the base plates are corrugated. Due to the waved shape of base plates 40 and their thickness, the base plates are elastic and provide a pretensioning force for heat source tubes 20 situated in-between. Each base plate 40 thus has a surface which faces the end face of heat source tubes 20 in order to press the heat source tubes together. On account of the waved shape it is also possible that the heat source tubes may shift relative to one another and in particular relative to abutting base plate 40, in particular under fairly intense thermal expansion, the offset distance of the shift being defined by the waved shape. Thus, there is a firm hold at any point in time, it being possible for the end faces of the tubes to shift to an adjacent (or in general, another) wave trough if a maximum radial force is exceeded. Openings are provided in base plate 40, at the level of the heat source tubes or at their end faces or end-face openings, which provide fluid communication between the heat source tubes and the space in the housing which in continuation adjoins the longitudinal extension of the tubes inside the housing. The housing thus forms chambers 70 in the heat source tubes and heat sink tubes. The openings in base plates 40 are such that, although exhaust gas, for example, is able to enter generally unhindered through the base plate into heat source tubes 20, heat source tubes at the same time are prevented from passing through the base plate due to their structure. In their longitudinal extension, the end faces of heat source tubes 20 are offset with respect to the end faces of heat sink tubes 30, the heat source tubes protruding beyond the heat sink tubes on both sides. This allows the base plate to be contacted solely by the heat source tubes. The base plate is fixedly connected to housing 50, for example via a weld seam or an integral bond. However, the end faces of heat source tubes 20 may move relative to the base plates, in particular relative to housing 50. In addition, curved elements 42 in the shape of a semicircle or a paraboloid, for example, which extends between two facing sides of the heat source tubes, may optionally be mounted on the base plate. Curved elements 42 may be welded to the base plate, or may have a one-piece design that is combined with the base plate, whereby the base plate does not extend along a plane at the positions of the curved elements. However, the base plate has an overall flat shape at the positions where the end faces of heat source tubes 20 contact the base plate (but as a macrostructure, it is provided with a waved shape). The curved elements in their transverse extension cover the distance which results between adjacent heat source tubes 20, and thus, in the projection in the longitudinal direction of the generator, cover heat sink tubes 30 and generator elements 10. The arrows illustrated by solid lines represent the flow of the exhaust gas, which enters into the particular flange at one side of the thermoelectric generator, is guided through heat source tubes 20, and exits on the opposite side. Arrows 80 show that optional curved element 42, illustrated by a dashed line, distributes the gas flow to adjacent heat source tubes 20 generally without turbulence.

The flow direction of heat sink tubes 30 is defined by the configuration of connections 32, 34, and may be parallel or antiparallel to the flow direction of the medium flowing through heat source tubes 20.

In the design illustrated in FIG. 1, the pretension mounting device is formed by wave-shaped base plates 40 and by the end faces of heat source tubes 20, on the one hand, as a result of the base plates the heat source tubes experiencing a compressive force, and on the other hand, due to the waved shape optionally together with heat-related changes in length the heat source tubes experiencing a radial force perpendicular to the longitudinal axis of the generator.

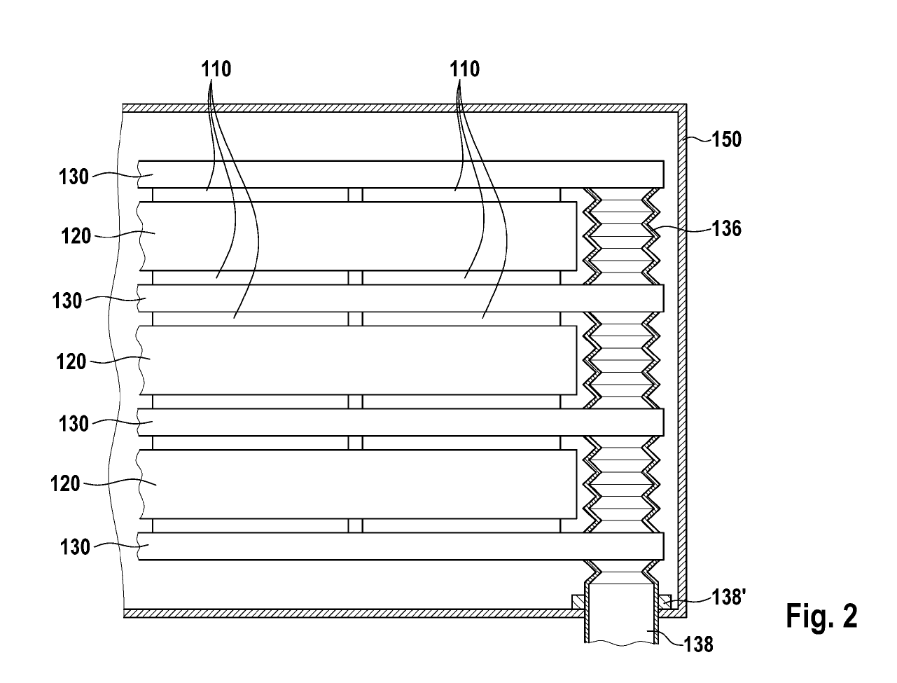

FIG. 2 shows a second specific embodiment of the present invention which is combinable with the specific embodiment illustrated with reference to FIG. 1. The generator illustrated in FIG. 2 includes generator elements 110 which are provided between heat source tubes 120 and heat sink tubes 130. FIG. 2 is a front view, i.e., a cross section of the longitudinal illustration in FIG. 1. It is initially apparent that the heat source tubes and the heat sink tubes have a flat, square cross section, so that the channel thus formed has a large circumference in relation to its cross-sectional area. This results in a high specific volume. Heat sink tubes 130 are connected to one another via a flexible connecting line or sections 136 thereof. The connecting line connects connections 32 and 34 of the heat sink tubes, i.e., the cooling channels, illustrated in FIG. 1. The connecting line is used as a collecting tube or as a collecting line for the cooling fluid, and has a connection 138 which protrudes through housing 150 and is sealed off from the housing by seals 138′. The specific embodiment illustrated in FIG. 2 provides that the collecting line or collecting line tube 136 is flexible and thus exerts generally no force on heat sink tubes 130. According to one specific embodiment not illustrated, collecting tube 136 is made of elastic material in order to provide lateral pretensioning for heat sink tubes 130. As a result of the pretensioning, adjacent heat sink tubes 130 are pulled toward one another, so that a pretension mounting device results from collecting tube 136. In addition to exerting a pretensioning force, an elastic collecting tube is also used for the mounting, together with the elements (i.e., heat source tubes 120 and generator elements 110) provided between heat sink tubes 130.

Collecting tube 136 (whether it is elastic or flexible) extends along an edge of the bundle formed by the heat source tubes and heat sink tubes and by the generator elements. Collecting tube 136 extends perpendicularly to the longitudinal plane of the bundle and at a vertical edge of the bundle. However, collecting tube 136 may also extend at the side of the bundle, i.e., perpendicular to the plane of extension of the bundle, and on a lateral surface of the bundle which extends along the direction of extension of the tubes. It is apparent with reference to FIGS. 1 and 2 that in the longitudinal direction, heat sink tubes 30; 130 are shorter than heat source tubes 20; 120, but in the transverse direction extend beyond same to allow provision of collecting line 136.

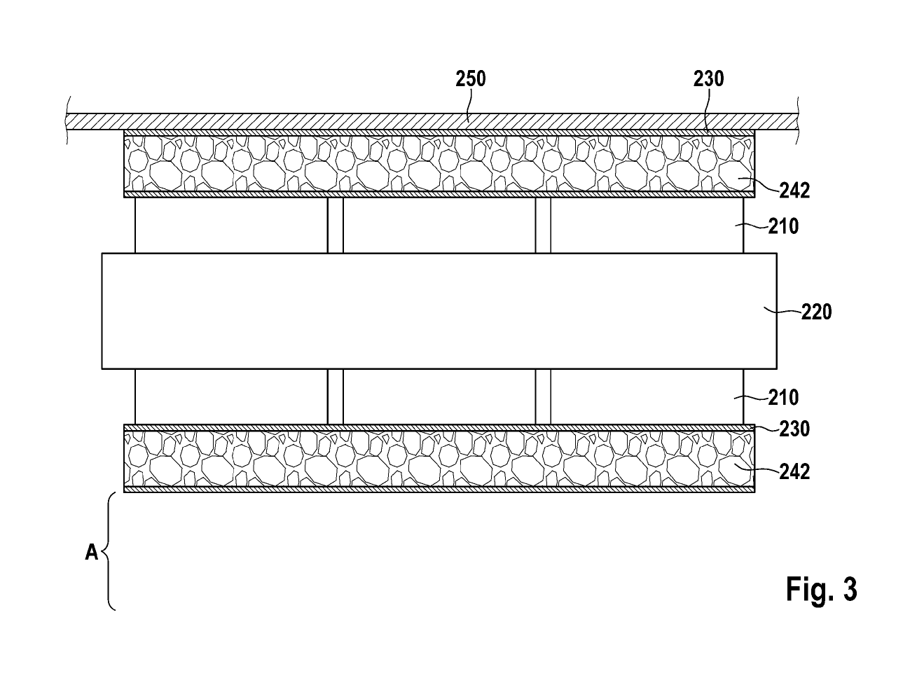

FIG. 3 shows a cross section of one alternative specific embodiment of the present invention in a schematic illustration. The generator illustrated in FIG. 3 includes generator elements 210 which are situated between a heat source tube 220 and heat sink tubes 230. A housing wall 250 supports a heat sink tube 230 as an example in this case, while an oppositely situated heat sink tube 230 is supported by consecutively following generator elements (and additional heat source tubes) in section A. The support is associated with pretensioning which compresses the two heat sink tubes 230 and line components 210, 220 in-between. Metal foam 242 is provided in heat sink tubes 230, which presses against the inner walls of the particular tubes 230. Tubes 230 are thin-walled, i.e., elastic or plastic, so that the pressure in the form of deformation may be externally transmitted. Thus, the tube wall of heat sink tubes 230 transmits the elastic force exerted by metal foam 242. At the same time, metal foam 242 is porous, i.e., has a flow-permeable structure, so that cooling agent may be conducted through cooling channel 230. The porosity of the metal foam results in greatly improved heat transfer, since the specific surface of the metal foam is much larger than the inner surface area of a tube. In addition, the metal foam results in a homogeneous action of force upon the inner wall of the tube. Due to the elasticity and other mechanical properties, the metal foam has a vibration-damping effect, in particular in that liquid is provided inside the metal foam, and therefore vibrations from (minor) turbulence or from external vibrations of the exhaust pipe are damped.

In addition, ribs are not provided for reinforcing tube 230, so that the tube may be manufactured having a rectangular cross section with a high aspect ratio, i.e., having a width that is several times the thickness. Furthermore, compared to channels having reinforcing ribs, the rigidity is homogeneous in the longitudinal direction and in the transverse direction of the channel. The damping properties of the metal foam directly result in an increase in the service life of the system, and prevent vibrations from causing heat gaps.

The specific embodiment illustrated in FIG. 3 is particularly suitable for slowly flowing cooling fluids, the low speed of the flow being more than compensated for by the substantially increased specific surface of the metal foam. In addition, material may be spared due to the small wall thickness of the channel or of the tube, resulting in a further reduction in weight. Due to the homogeneous distribution of the pretensioning through the metal foam, it is not necessary to use force-distributing elements. In principle, the metal foam may be used in the heat source tube or in the heat sink tube. However, the metal foam is preferably situated in the heat sink tube, since the low temperatures allow use of foams made of various materials. In addition to metal foams, for example plastic foams or other materials may be used as long as they have a structure which allows flow in the longitudinal direction. Furthermore, in principle, instead of the metal foam an internal tube under radial tension and which generates an outwardly acting radial force may be introduced into the heat sink tube. In principle, this type of radial force may also be generated by a pressure difference which exists between the interior of the heat sink tube and the surroundings of the heat sink tube. Provided that the heat sink tube or heat source tube is flexible or elastic, the desired pretensioning may be achieved by a positive pressure if the tubes experience an external counterforce through a housing inner wall.

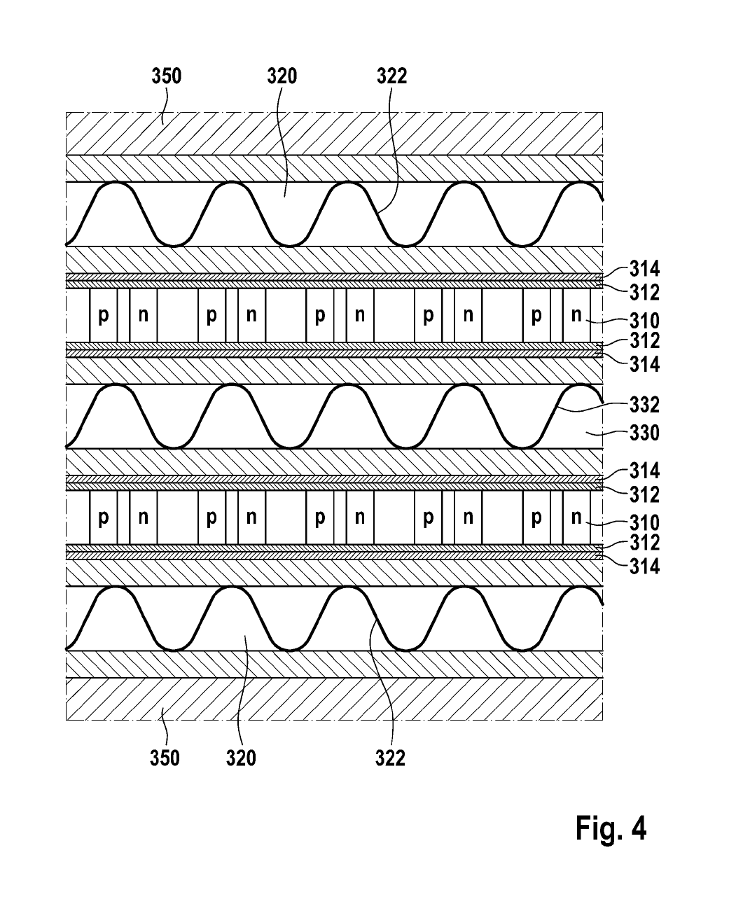

FIG. 4 illustrates a fourth specific embodiment of the thermoelectric generator according to the present invention in the cross section, which includes a housing 350 in which thermoelectric elements 310, heat source tubes 320, and a heat sink tube 330 are provided. Generator elements 310 include semiconductor legs, arranged in pairs, which are differently doped in alternation (p- and n-doped). Generator elements 310 also include printed conductors (not illustrated) situated at the end faces of the generator elements. The generator elements are connected to the outer tube walls of heat source tube 320 on one side and to heat sink tube 330 on the other side via a heat-conducting paste layer 312 having an electrically insulating layer made of ceramic 314, for example. This results in a temperature difference for the generator elements, on the basis of which the generator elements generate electrical power.

Spring elements 322 and 332 are provided inside heat source tubes 320 and heat sink tube 330, respectively, and exert pressure directly on the inner walls of the particular tube. Lower heat source tube 320 is formed by a tube wall, and on the opposite side, is formed by the inner surface of housing 350. Lower heat source tube 320 is thus provided by an internal shell which insulates the heat source medium as well as surrounding housing 350 from the generator elements. Material and space are thus spared; due to the dual use of a shell between the heat source medium and the heat sink medium, a tube wall may be spared, at least for outer tubes 320 (or also 330). In this regard the inner wall of housing 350, in contrast to upper heat source tube 320, also has a dual function, in that on the one hand the housing provides a stable border as a counterbearing for the elastic forces, and on the other hand provides the fluid-conducting properties of a heat source tube or heat sink tube.

Spring elements 322 contact the inner sides of the tubes (or, in the case of the lower heat source tube, contact the inner side of the housing), and thus exert a pressure on the adjacent generator elements and on the additional tubes. To allow this, the walls of tubes 320, 330 used are elastic or flexible to enable a deformation to be transmitted through spring elements 332 to exterior components. Spring elements 332 are only symbolically illustrated in FIG. 4; in particular, leaf springs, spiral springs, or wire springs which preferably extend along the entire tube may be used. Optionally, spring elements may also be provided which are situated only in longitudinal sections of the tubes or act on same, in this case a force distribution element being provided to distribute the elastic force generally homogeneously over the inner wall sides of tubes 320, 330. These types of elastic force transmission elements or elements for homogenizing the action of force may be formed by two halves of a cylinder jacket, between which the spring elements are situated. Depending on the design of the tube wall, however, these elements take over the function of homogenizing the action of force.

The illustration in FIG. 4 as well as the illustrations in FIGS. 1 through 3 are symbolic and not to scale, in particular with regard to the thickness of the tube walls when these are designed as flexible or as elastic structures. In general, the heat source tubes and the heat sink tubes form a channel having a rectangular cross section, in particular a cross section having a high aspect ratio. The high aspect ratio (width to height) allows the tubes to provide a large outer surface or inner surface in comparison to a small volume. The tubes preferably extend in parallel to one another, and may be lined up next to one another according to their height or their width. The generator elements are stacked in particular between the tubes in a direction which is perpendicular to the direction of extension of the generator. However, generator elements may also be provided between the tubes in the transverse extension of the generator. The generator elements are preferably coupled to the outer surfaces of the heat source tubes or heat sink tubes via a heat-transmitting element, for example with the aid of a layer having good thermal conduction. This layer preferably has an electrically insulating design so that, for example, materials such as ceramic, Al₂O₃, AlN, steatite, fosterite, enamel, or the like are suitable. If the layer having good thermal conduction is not completely electrically insulated, a further electrically insulating element, preferably having a small thickness, is used to provide additional electrical insulation. As illustrated in FIG. 4, the individual generator elements or their thermoelectrically active bodies over a contact layer (a printed conductor, for example) are thermally connected to the outer walls of the tubes only via a thermally connecting element, for example an electrically insulating and thermally conductive layer.

As illustrated in FIG. 4, all tubes, i.e., all heat source tubes and heat sink tubes, bear spring elements 322, 332 inside. However, this may involve only some of the tubes, for example only the heat sink tubes or only the heat source tubes, whereby all similar tubes do not necessarily have to bear a spring element. The spring element in particular is not only provided in a tube which directly adjoins the housing, but is also provided in a heat sink tube or heat source tube which is present inside the generator and which does not directly adjoin the housing. This results in pretensioning which not only originates in the outer border of the generator, in particular in a border which directly adjoins the housing, but which also acts within the stack. This results in more robust, vibration-resistant, and homogeneous compression of the tubes and the generator elements.

1-10. (canceled)

11. A thermoelectric generator, comprising:
a housing in which at least one heat source tube, at least one heat sink tube, and at least one generator element situated between the heat source tube and the heat sink tube are situated; and
a pretension mounting device provided in the housing, the pretension mounting device configured to provide an elastic force which directly acts upon at least a portion of at least one of the heat source tubes and the heat sink tubes, pretensions the at least one of the heat source tubes and the heat sink tubes relative to one another, and compresses the at least one of the heat source tubes and the heat sink tubes and the generator element situated in-between, an inner side of the housing providing a support for the pretension mounting device which is acted upon by a counterforce to the elastic force of the pretension mounting device.

12. The thermoelectric generator as recited in claim 11, wherein the pretension mounting device includes two base plates which are fixedly connected to the housing, the at least one of the heat source tubes and the heat sink tubes being clamped longitudinally between surfaces of the base plates facing the at least one of the heat source tubes and the heat sink tubes, and having one of micro- or macrostructures which at end faces of the at least one of the heat source tubes and the heat sink tubes form one of a force fit having a defined maximum adhesive force, or a form fit which is detachable by a defined maximum radial force, and the pretension mounting device being formed by the base plates, surfaces, and the end faces of the at least one of the heat source tubes and the heat sink tubes.

13. The thermoelectric generator as recited in claim 12, wherein at least one of the base plates, and the at least one of the heat source tubes and the heat sink tubes, are made of at least slightly elastic material, a maximum adhesive force and a maximum radial force being defined by the elasticity of the elastic material and by a height of the one of the micro- or macrostructure, the pretension mounting device supporting the at least one of the heat source tubes and the heat sink tubes with two degrees of freedom in directions extending along the surfaces, and pretensioning which acts upon the at least one of the heat source tubes and the heat sink tubes and which is generated by elasticity of one of the base plates or the at least one of the heat source tubes and the heat sink tubes also extending along the pretension mounting device.

14. The thermoelectric generator as recited in claim 12, wherein one of the surfaces or the base plates, as macrostructures, have one of a wave-shaped profile or a grid pattern which has repetitive one of elevations or depressions along the surface in at least two directions.

15. The thermoelectric generator as recited in claim 11, wherein the pretension mounting device includes spring elements which are situated inside the at least one of the heat sink tubes or the heat source tubes, under pretensioning in the at least one of the heat sink tubes or the heat source tubes, the pretensioning of the spring elements acting on oppositely situated sections of inner sides of the one of the one of the heat sink tube or the heat source tube, radially outwardly with respect to the inner sides, and the at least one of the heat sink tubes or the heat source tubes in which the spring elements are provided having an elastic design in order to transmit the pretensioning to an adjacent tube.

16. The thermoelectric generator as recited in claim 11, wherein the pretension mounting device include includes spring elements situated between end sections of one of multiple heat sink tubes that extend beyond the heat source tubes, the pretension of the spring elements pressing on oppositely situated sections.

17. The thermoelectric generator as recited in claim 15, wherein the spring elements are situated inside the one of the heat sink tubes or the heat source tubes, and an elastic design of the tubes in which the spring elements are situated is provided by a design of a wall thickness and of a material of the one of the heat sink tubes or the heat source tubes which enables a cross section of the one of the heat sink tubes or the heat source tubes to be changed by the spring elements, the spring elements having a structure which is permeable to flow, the spring elements being one of: i) provided by one of leaf springs or wire springs which are pretensioned in the tube, or ii) provided by metal foam which is pretensioned in the tube.

18. The thermoelectric generator as recited in claim 16, wherein the spring elements are provided between end sections of the one of the heat sink tube or the heat source tube, and the spring elements are provided by sections of a collecting tube which is elastic in a longitudinal direction and which connects multiple ones of the one of the first heat sink tubes or the heat source tubes, which form the end sections, to one another in fluid communication, an elastic collecting tube providing the pretensioning between the end sections.

19. The thermoelectric generator as recited in claim 11, wherein the one of the heat sink tubes or the heat source tubes are connected to one another in fluid communication at their end sections via a flexible collecting tube which exerts no force on the tubes, and the elastic force of the pretension mounting device provides all of the pretensioning between the one of the heat sink tubes or the heat source tubes.

20. The thermoelectric generator as recited in claim 11, further comprising:
a flow control system which is situated at end faces of the heat sink tubes and the heat source tubes and which at its inner side is tapered toward the heat sink tubes and the heat source tubes, a collecting chamber being provided on at least one of the end faces inside the housing, and being in fluid contact with one of: all heat source tubes or all heat sink tubes of the generator, the flow control system being provided between the collecting chamber and the end faces of the tubes.

21. A method for manufacturing a thermoelectric generator, comprising:
introducing at least one heat source tube, at least one heat sink tube, and at least one generator element into a housing; and
situating a pretension mounting device in the housing which generates an elastic force for exerting pretensioning, via which the heat sink tubes and the heat source tubes are directly pretensioned against one another, and via which the heat sink tubes and the heat source tubes compress the generator element situated in-between, wherein one of: i) the heat sink tubes and the heat source tubes are clamped in the pretension mounting device, or ii) the pretension mounting device is clamped in the heat sink tubes or the heat source tubes, and wherein the heat sink tubes and the heat source tubes are acted upon by a force through an inner side of the housing via which the pretension mounting device is supported.
